(19) United States
(12) Patent Application Publication
(10) Pub. No.: US 2016/0233368 A1
(43) Pub. Date: Aug. 11, 2016

(54) SOLAR CELL

(71) Applicant: Panasonic Intellectual Property Management Co., Ltd., Osaka (JP)

(72) Inventor: Akiyoshi OGANE, Aichi (JP)

(73) Assignee: Panasonic Intellectual Property Management Co., Ltd., Osaka (JP)

(21) Appl. No.: 15/131,033

(22) Filed: Apr. 18, 2016

Related U.S. Application Data
(63) Continuation of application No. PCT/JP2014/077328, filed on Oct. 14, 2014.

(30) Foreign Application Priority Data
Nov. 1, 2013 (JP) 2013-227927

(51) Int. Cl. H01L 31/0747; H01L 31/0224; H01L 31/0352

(52) U.S. Cl. CPC H01L 31/0747; H01L 31/035281; H01L 31/022466

(57) ABSTRACT

A solar cell includes: an n-type crystalline silicon substrate having a first major surface and a second major surface opposite the first major surface; an n-type amorphous silicon film on a first major surface side; and a p-type amorphous silicon film on a second major surface side, wherein the n-type amorphous silicon film has a tapered region which tapers toward an edge of the n-type amorphous silicon film in a manner that a thickness of the edge in a planar direction of the n-type amorphous silicon film is less than a thickness of a central portion of the n-type amorphous silicon film in the planar direction.

### CROSS REFERENCE TO RELATED APPLICATION

This application is a U.S. continuation application of PCT International Patent Application Number PCT/JP2014/077328 filed Oct. 14, 2014, claiming the benefit of priority of Japanese Patent Application Number 2013-227927 filed on Nov. 1, 2013, the entire contents of which are hereby incorporated by reference.

### BACKGROUND

1. Technical Field

The present disclosure relates to a solar cell.

2. Description of the Related Art

In crystalline silicon based solar cells, a p-type amorphous silicon film is formed on a major surface side of an n-type crystalline silicon substrate, and an n-type amorphous silicon film is formed on a rear surface side of the n-type crystalline silicon substrate. In this case, the respective amorphous silicon films are formed wrapping around the side and rear surfaces of the n-type crystalline silicon substrate, and thus the crystalline silicon based solar cells are known to be susceptible to leakage current problems caused by the p-type amorphous silicon film and n-type amorphous silicon film being brought into contact with each other on the side surface of the n-type crystalline silicon substrate. To prevent this, it is known to provide, at an edge of the n-type crystalline silicon substrate, a region where the n-type amorphous silicon film is not formed, as shown in FIG. 6 of Japanese Unexamined Patent Application Publication No. 2006-237363.

### SUMMARY

However, since no passivation film is formed in the region where the n-type amorphous silicon film is not formed, the region is a waste region and does not contribute to generating electric power. This is detrimental from the standpoint of cell properties.

An object of the present disclosure is to provide a solar cell which can prevent contact of the p-type amorphous silicon film and the n-type amorphous silicon film, thereby preventing generation of leakage current, and enhancing cell properties.

A solar cell according to one aspect of the present disclosure includes: an n-type crystalline silicon substrate having a first major surface and a second major surface opposite the first major surface; an n-type amorphous silicon film on a first major surface side; and a p-type amorphous silicon film on a second major surface side, wherein the n-type amorphous silicon film has a tapered region which tapers toward an edge of the n-type amorphous silicon film in a manner that a thickness of the edge in a planar direction of the n-type amorphous silicon film is less than a thickness of a central portion of the n-type amorphous silicon film in the planar direction.

According to the present disclosure, generation of leakage current due to contact of the p-type amorphous silicon film and the n-type amorphous silicon film can be prevented, and cell properties can be enhanced.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a schematic cross-sectional view of a solar cell according to exemplary Embodiment 1;

FIG. 2 is a schematic plan view of the solar cell according to exemplary Embodiment 1;

FIG. 3 is a schematic cross-sectional view of a solar cell according to exemplary Embodiment 2;

FIG. 4 is a schematic cross-sectional view of a solar cell according to exemplary Embodiment 3;

FIG. 5 is a schematic cross-sectional view of a solar cell according to exemplary Embodiment 4;

FIG. 6 is a schematic cross-sectional view for illustrating a method for forming an amorphous silicon film having a tapered region; and

FIG. 7 is a schematic cross-sectional view for illustrating a method for forming an amorphous silicon film having no tapered region.

### DETAILED DESCRIPTION OF THE EMBODIMENTS

Hereinafter, embodiments are described with reference to the accompanying drawings. However, the embodiments below are merely illustrative, and the present disclosure is not limited to the embodiments below. The same reference signs may be given in the figures to refer to components that have substantially the same functionality.

### Exemplary Embodiment 1

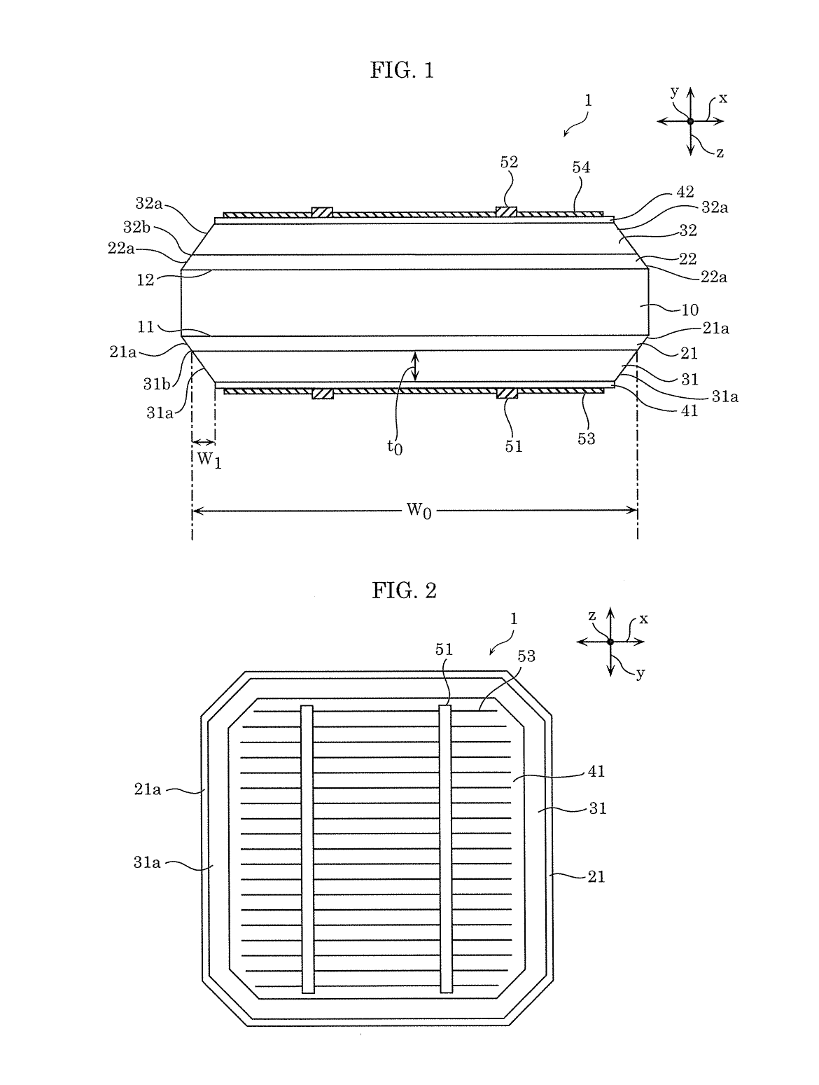

FIG. 1 is a schematic cross-sectional view of solar cell 1 according to Embodiment 1. FIG. 2 is a schematic plan view of solar cell 1 according to Embodiment 1. Solar cell 1 shown in FIGS. 1 and 2 includes n-type crystalline silicon substrate 10. N-type crystalline silicon substrate 10 has first major surface 11 and second major surface 12. On first major surface 11, first intrinsic amorphous silicon film 21 is formed. On first intrinsic amorphous silicon film 21, n-type amorphous silicon film 31 is formed. On n-type amorphous silicon film 31, first electrode layer 41 is formed. On first electrode layer 41, busbar electrode 51 and finger electrode 53 are formed.

On second major surface 12 of n-type crystalline silicon substrate 10, second intrinsic amorphous silicon film 22 is formed. On second intrinsic amorphous silicon film 22, p-type amorphous silicon film 32 is formed. On p-type amorphous silicon film 32, second electrode layer 42 is formed. On second electrode layer 42, busbar electrode 52 and finger electrode 54 are formed.

N-type crystalline silicon substrate 10 may be formed of monocrystalline silicon, or may be formed of poly-crystalline silicon. The “amorphous silicon” as used herein includes microcrystalline silicon. Microcrystalline silicon refers to amorphous silicon in which silicon crystals are precipitated.

In the present embodiment, n-type amorphous silicon film 31 has tapered region 31a. Tapered region 31a tapers toward edge 31b in a manner that a thickness of edge 31b of n-type amorphous silicon film 31 in a planar direction (x-y plane) is less than thickness to of a central portion of n-type amorphous silicon film 31 in the planar direction (x-y plane).

In the present embodiment, in forming n-type amorphous silicon film 31, tapered region 31a is formed at edge 31b of n-type amorphous silicon film 31, thereby preventing n-type amorphous silicon film 31 from wrapping around the side surface of n-type crystalline silicon substrate 10. This therefore prevents contact of n-type amorphous silicon film 31 and p-type amorphous silicon film 32 on the side surface of n-type crystalline silicon substrate 10, thereby preventing generation of leakage current.

In the present embodiment, n-type crystalline silicon substrate 10 has no region where the n-type amorphous silicon film is not formed as conventional technology. Thus, the present embodiment can enhance the efficiency of solar cell power generation and solar cell passivation. Thus, the present embodiment can enhance the cell properties.

Preferably, tapered region 31a tapers in a manner that a thickness of edge 31b of n-type amorphous silicon film 31 is 50% or less than thickness to of the central portion of n-type amorphous silicon film 31. Preferably, tapered region 31a has width W₁ in the planar direction within a range of at least 0.1% to at least 2% of overall width W₀ of n-type amorphous silicon film 31 in the planar direction.

Moreover, in the present embodiment, first intrinsic amorphous silicon film 21 has tapered region 21a. Tapered region 21a tapers having a taper angle substantially the same as a taper angle of tapered region 31a.

Moreover, in the present embodiment, p-type amorphous silicon film 32 has tapered region 32a the same or similar to tapered region 31a of n-type amorphous silicon film 31. In other words, p-type amorphous silicon film 32 has tapered region 32a which tapers toward edge 32b in a manner that a thickness of edge 32b of p-type amorphous silicon film 32 in a planar direction is less than a thickness of the central portion of p-type amorphous silicon film 32 in the planar direction. Thus, in forming p-type amorphous silicon film 32 also, p-type amorphous silicon film 32 can be prevented from wrapping around the side surface of n-type crystalline silicon substrate 10, thereby preventing contact of n-type amorphous silicon film 31 and p-type amorphous silicon film 32 on the side surface of n-type crystalline silicon substrate 10. Second intrinsic amorphous silicon film 22 has tapered region 22a. Tapered region 22a tapers having a taper angle substantially the same as a taper angle of tapered region 32a.

Preferably, dopant concentration of n-type amorphous silicon film 31 is higher than dopant concentration of first intrinsic amorphous silicon film 21, and is 1×10²⁰ cm⁻³ or more. Preferably, thickness t₀ of n-type amorphous silicon film 31 is sufficiently thick to efficiently separate carriers generated in n-type crystalline silicon substrate 10 at a junction, and allow first electrode layer 41 to efficiently collect the carriers. Specifically, preferably, thickness t₀ of n-type amorphous silicon film 31 is 1 nm or greater and 50 nm or less.

Dopant concentration of p-type amorphous silicon film 32 is higher than the dopant concentration of second intrinsic amorphous silicon film 22, and, preferably, 1×10²⁰ cm⁻³ or more. Preferably, a thickness of p-type amorphous silicon film 32 is sufficiently thin to absorb light as little as possible, and, at the same time, sufficiently thick to effectively separate the carriers generated by a photoelectric conversion unit at a junction, and allow second electrode layer 42 to efficiently collect the carriers. Specifically, the thickness of p-type amorphous silicon film 32 is, preferably, 1 nm or greater and 50 nm or less.

Preferably, p-type dopant concentration or n-type dopant concentration of first and second intrinsic amorphous silicon films 21 and 22 is 5×10¹⁸ cm⁻³ or less. Preferably, thicknesses of intrinsic amorphous silicon films 21 and 22 are sufficiently thin to reduce the absorption of light as much as possible, and, at the same time, sufficiently thick to adequately passivate the surface of n-type crystalline silicon substrate 10. Specifically, the thicknesses of intrinsic amorphous silicon films 21 and 22 are, preferably, 1 nm or greater and 25 nm or less, and more preferably, 2 nm or greater and 10 nm or less.

In the present embodiment, first and second electrode layers 41 and 42 are transparent electrodes. In solar cell 1 according to the present embodiment, the second major surface 12 side may be a light receiving surface side, or the first major surface 11 side may be the light receiving surface side. Alternatively, solar cell 1 according to the present embodiment may be a bifacial solar cell.

Preferably, thicknesses of first and second electrode layers 41 and 42 are 50 nm or greater and 150 nm or less, and more preferably, 70 nm or greater and 120 nm or less. Bringing the thicknesses of first and second electrode layers 41 and 42 into within the above range allows reduction of the absorption of incident light and prevention of an increase of electric resistance.

Busbar electrodes 51 and 52 and finger electrodes 53 and 54 may be formed by a method of forming a busbar electrode and finger electrode in a common solar cell. For example, busbar electrodes 51 and 52, and finger electrodes 53 and 54 can be formed by printing a silver (Ag) paste over first and second electrode layers 41 and 42. While the busbar electrodes are formed in the present embodiment, solar cell 1 according to the present embodiment may have a busbar-less structure in which no busbar electrode is formed.

### Exemplary Embodiment 2

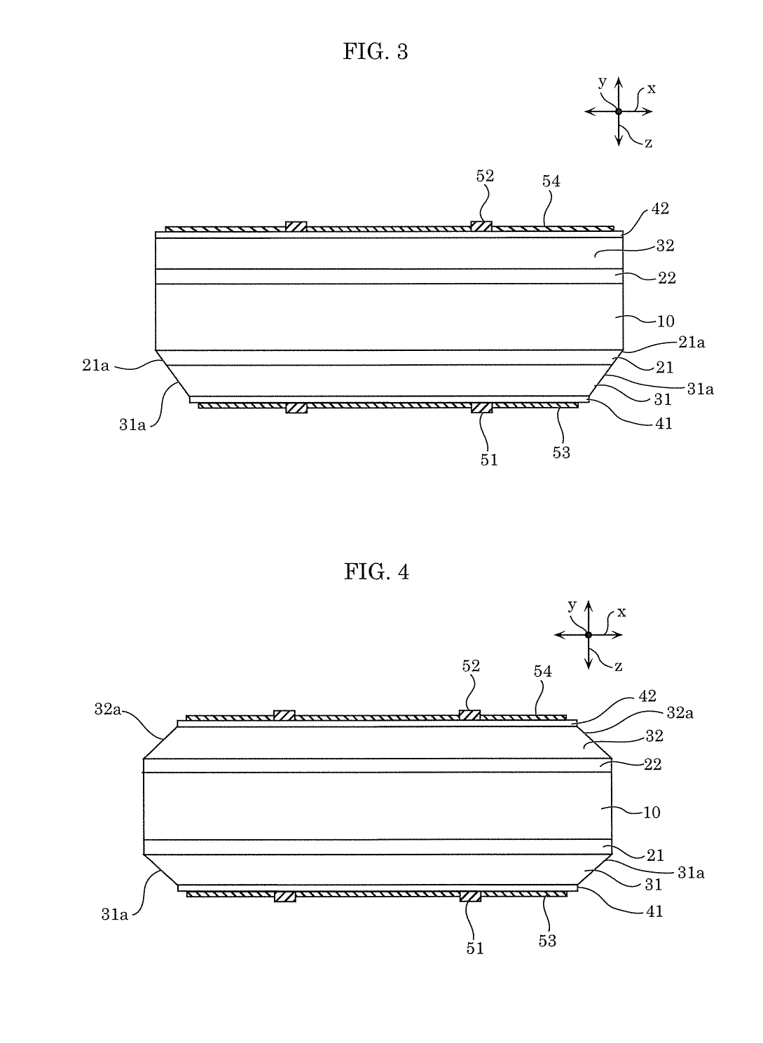

FIG. 3 is a schematic cross-sectional view of a solar cell according to Embodiment 2. In the present embodiment, p-type amorphous silicon film 32 and second intrinsic amorphous silicon film 22 have no tapered region. The present embodiment is otherwise the same as Embodiment 1. Thus, the present embodiment can also prevent contact of n-type amorphous silicon film 31 and p-type amorphous silicon film 32, and prevent generation of leakage current. In addition, the present embodiment can enhance the efficiency of solar cell power generation and solar cell passivation, thereby enhancing the cell properties.

### Exemplary Embodiment 3

FIG. 4 is a schematic cross-sectional view of a solar cell according to Embodiment 3. In the present embodiment, first intrinsic amorphous silicon film 21 and second intrinsic amorphous silicon film 22 have no tapered region. The present embodiment is otherwise the same as Embodiment 1. Thus, first intrinsic amorphous silicon film 21 and second intrinsic amorphous silicon film 22 each have substantially the same thickness across n-type crystalline silicon substrate 10. Owing to this, the solar cell according to Embodiment 3 can enhance solar cell passivation as compared to Embodiment 1. The present embodiment can also prevent contact of n-type amorphous silicon film 31 and p-type amorphous silicon film 32, and prevent generation of leakage current. In addition, the present embodiment can enhance the efficiency of solar cell power generation and solar cell passivation, thereby enhancing the cell properties.

### Exemplary Embodiment 4

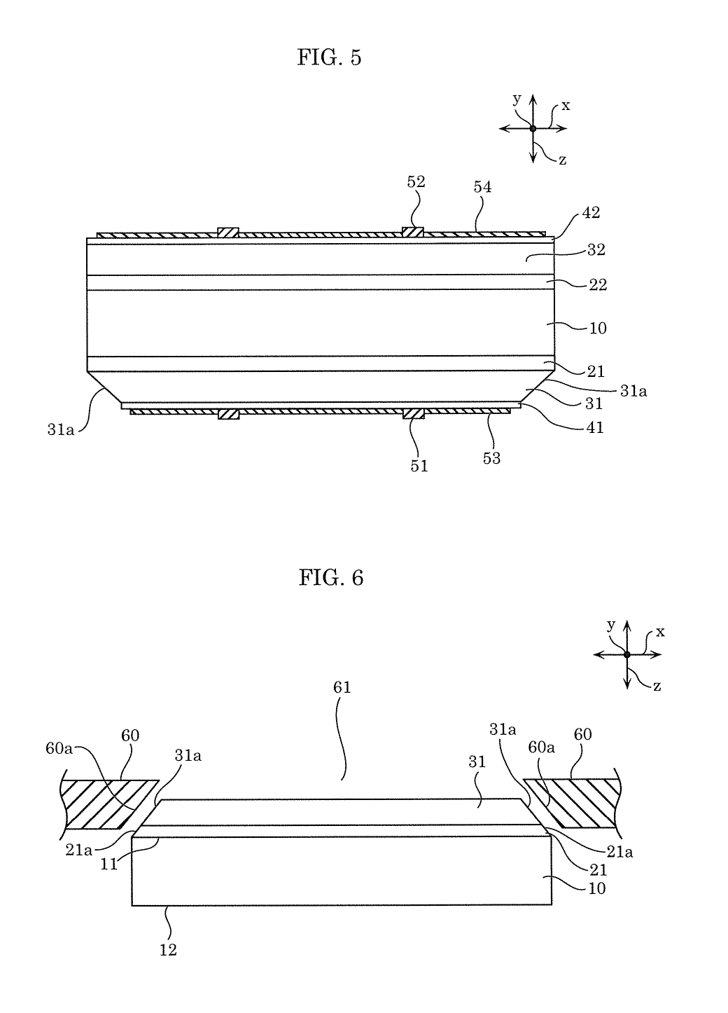

FIG. 5 is a schematic cross-sectional view of a solar cell according to Embodiment 4. In the present embodiment, first intrinsic amorphous silicon film 21 according to the present embodiment has no tapered region. The present embodiment is otherwise the same as Embodiment 2. Thus, first intrinsic amorphous silicon film 21 has substantially the same thickness across n-type crystalline silicon substrate 10. Owing to this, the solar cell according to Embodiment 3 can enhance solar cell passivation as compared to Embodiment 2. The present embodiment can also prevent contact of n-type amorphous silicon film 31 and p-type amorphous silicon film 32, and prevent generation of leakage current. In addition, the present embodiment can enhance the efficiency of solar cell power generation and solar cell passivation, thereby enhancing the cell properties.

In Embodiments 1 to 4 described above, first intrinsic amorphous silicon film 21 is formed between n-type amorphous silicon film 31 and n-type crystalline silicon substrate 10, and second intrinsic amorphous silicon film 22 is formed between p-type amorphous silicon film 32 and n-type crystalline silicon substrate 10. The present disclosure, however, is not limited thereto. N-type amorphous silicon film 31 and p-type amorphous silicon film 32 may be directly disposed on opposing surfaces of n-type crystalline silicon substrate 10.

While the p-n junction is formed on the second major surface 12 side in Embodiments 1 to 4 described above, the p-n junction may be formed on the first major surface 11 side.

### Method of Fabrication

Each of the layers of solar cell 1 may be formed in the following manner. First, preferably, the surface of n-type crystalline silicon substrate 10 is cleaned prior to depositing the layers. Specifically, the surface of n-type crystalline silicon substrate 10 may be cleaned using hydrofluoric acid solution or RCA cleaning fluid. For example, the front and rear sides of n-type crystalline silicon substrate 10 are textured using an alkaline etchant such as potassium hydroxide solution (KOH solution), for example. In this case, n-type crystalline silicon substrate 10 that is textured and has a pyramid (111) plane can be formed by anisotropically etching n-type crystalline silicon substrate 10 having a (100) plane, using an alkaline etchant.

For example, in order to improve compatibility between n-type crystalline silicon substrate 10 and first intrinsic amorphous silicon film 21 and between n-type crystalline silicon substrate 10 and second intrinsic amorphous silicon film 22, n-type crystalline silicon substrate 10 may have undergone a predetermined oxidation process and have oxidized interfaces formed on the first and second major surfaces of n-type crystalline silicon substrate 10, prior to the deposition of first intrinsic amorphous silicon film 21 and second intrinsic amorphous silicon film 22. As the predetermined oxidation process, accordingly, n-type crystalline silicon substrate 10 may be left in the air or humidity-controlled atmosphere for a predetermined length of time, or ozone water treatment, treatment using hydrogen peroxide solution, or treatment using ozonizer, for example, may be conducted on n-type crystalline silicon substrate 10.

First intrinsic amorphous silicon film 21, second intrinsic amorphous silicon film 22, n-type amorphous silicon film 31, and p-type amorphous silicon film 32 may be formed, for example, by plasma-enhanced chemical vapor deposition, thermal chemical vapor deposition, photochemical vapor deposition, and sputtering. For plasma-enhanced chemical vapor deposition, either one of the following approaches may be used: RF plasma; VHF plasma; and microwave plasma. If RF plasma-enhanced chemical vapor deposition is used, for example, a silicon contained gas such as silane (SiH₄), a p-type dopant contained gas such as diborane (B₂H₆), and an n-type dopant contained gas such as phosphine (PH₃), which are diluted with hydrogen, and are turned into plasma by applying RF high frequency power to a parallel-plate electrode or the like. The plasma is then supplied to the heated surface of n-type crystalline silicon substrate 10, thereby forming first intrinsic amorphous silicon film 21, second intrinsic amorphous silicon film 22, n-type amorphous silicon film 31, and p-type amorphous silicon film 32. It should be noted that preferably, a substrate temperature at the deposition of the films is in a range from at least 150 degrees Celsius to at least 250 degrees Celsius. Preferably, RF power density at the deposition of the films is in a range from at least 1 mW/cm² to at least 10 mW/cm².

FIG. 6 is a schematic cross-sectional view for illustrating a method for forming an amorphous silicon film having a tapered region. As illustrated in FIG. 6, mask 60 is placed on first major surface 11 of n-type crystalline silicon substrate 10. Mask 60 has opening 61. End face 60a defining opening 61 of mask 60 tapers in a manner that opening 61 increases toward first major surface 11. Such a mask 60 is placed on first major surface 11 of n-type crystalline silicon substrate 10. First intrinsic amorphous silicon film 21 and n-type amorphous silicon film 31 are deposited one after another on first major surface 11 in this state by the above mentioned approach such as plasma-enhanced chemical vapor deposition, for example, thereby forming first intrinsic amorphous silicon film 21 and n-type amorphous silicon film 31 that have tapered region 21a and tapered region 31a, respectively. Second intrinsic amorphous silicon film 22 and p-type amorphous silicon film 32 according to Embodiment 1 which respectively have tapered region 22a and tapered region 32a may also be formed in the same manner.

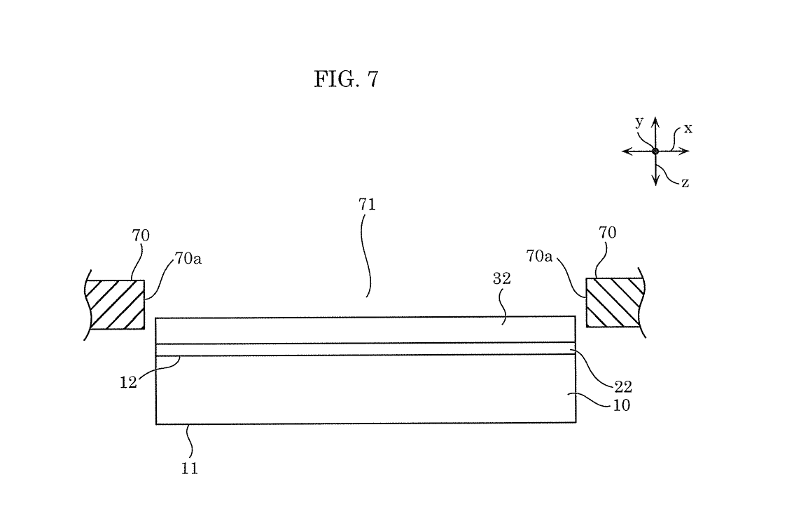

FIG. 7 is a schematic cross-sectional view for illustrating a method for forming an amorphous silicon film having no tapered region. As illustrated in FIG. 7, mask 70 is placed on second major surface 12 of n-type crystalline silicon substrate 10. Mask 70 has opening 71. End face 70a defining opening 71 of mask 70 is formed extending in the vertical direction (z-direction). End face 70a is not tapered as end face 60a of mask 60 illustrated in FIG. 6. Such a mask 70 is placed on second major surface 12 of n-type crystalline silicon substrate 10. Second intrinsic amorphous silicon film 22 and p-type amorphous silicon film 32 are deposited one after another on second major surface 12 in this state by the above mentioned approach such as plasma-enhanced chemical vapor deposition, for example, thereby forming second intrinsic amorphous silicon film 22 and p-type amorphous silicon film 32 which have no tapered region.

Second intrinsic amorphous silicon film 22 and p-type amorphous silicon film 32 according to Embodiments 2 and 4 may be formed by such a method as illustrated in FIG. 7. Likewise, first intrinsic amorphous silicon film 21 and second intrinsic amorphous silicon film 22 according to Embodiments 3 and 4 may be formed by such a method as well.

In Embodiment 3, first intrinsic amorphous silicon film 21 and second intrinsic amorphous silicon film 22 are formed in this manner, and n-type amorphous silicon film 31 and p-type amorphous silicon film 32 are then formed by the method illustrated in FIG. 6. In Embodiment 4, first intrinsic amorphous silicon film 21 is formed as described above, and then n-type amorphous silicon film 31 is formed by the method illustrated in FIG. 6. While the foregoing has described what are considered to be the best mode and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A solar cell comprising:
an n-type crystalline silicon substrate having a first major surface and a second major surface opposite the first major surface;
an n-type amorphous silicon film on a first major surface side; and
a p-type amorphous silicon film on a second major surface side, wherein
the n-type amorphous silicon film has a tapered region which tapers toward an edge of the n-type amorphous silicon film in a manner that a thickness of the edge in a planar direction of the n-type amorphous silicon film is less than a thickness of a central portion of the n-type amorphous silicon film in the planar direction.

2. The solar cell according to claim 1, wherein
the tapered region tapers in a manner that the thickness of the edge of the n-type amorphous silicon film is 50% or less than the thickness of the central portion.

3. The solar cell according to claim 1, wherein
a width of the tapered region in the planar direction is in a range of 0.1% to 2% of an overall width of the n-type amorphous silicon film in the planar direction.

4. The solar cell according to claim 1, wherein
the p-type amorphous silicon film has a tapered region which tapers toward an edge of the p-type amorphous silicon film in a manner that a thickness of the edge of the p-type amorphous silicon film in a planar direction of the p-type amorphous silicon film is less than a central portion of the p-type amorphous silicon film in the planar direction of the p-type amorphous silicon film.

5. The solar cell according to claim 1, further comprising:
a first intrinsic amorphous silicon film between the n-type amorphous silicon film and the n-type crystalline silicon substrate; and
a second intrinsic amorphous silicon film between the p-type amorphous silicon film and the n-type crystalline silicon substrate.
